(19) United States
(12) Patent Application Publication
(10) Pub. No.: US 2026/0152384 A1
(43) Pub. Date: Jun. 4, 2026

(54) MEMS DEVICE WITH COMPENSATION OF THE MECHANICAL STRESS AND RELATED MANUFACTURING PROCESS

(71) Applicant: STMicroelectronics International N.V., Geneva (CH)

(72) Inventors: Silvia NICOLI, Briosco (IT); Igor VARISCO, Settimo Milanese (IT); Filippo DANIELE, Milano (IT); Lorenzo TENTORI, Verano Brianza (IT); Filippo D'ERCOLI, Milano (IT); Federica CAPRA, Carpaneto Piacentino (IT)

(73) Assignee: STMicroelectronics International N.V., Geneva (CH)

(21) Appl. No.: 18/819,679

(22) Filed: Aug. 29, 2024

(30) Foreign Application Priority Data
Sep. 8, 2023 (IT) 102023000018465

(51) Int. Cl. B81B 3/00; B81C 1/00

(52) U.S. Cl. CPC B81B 3/0072; B81B 3/0021; B81C 1/00666; B81B 2203/0118; B81C 2201/0116

(57) ABSTRACT

A micro-electro-mechanical (MEMS) device is provided that includes a fixed body delimiting a cavity; a suspended structure extending cantilevered from the fixed body, above the cavity, and including a suspended semiconductive region; and a transducer arranged above the suspended structure. The suspended structure further includes a compensation region of thermal oxide, which extends below the suspended semiconductive region. A method of manufacturing a MEMS device is also provided.

### BACKGROUND

### Technical Field

Embodiments of the present disclosure relate to a micro-electro-mechanical (MEMS) device with compensation of the mechanical stress and to a related manufacturing process.

### Description of the Related Art

Micro-electro-mechanical (MEMS) devices that envisage the presence of a cantilever are very widespread.

For example, FIG. 1 shows a MEMS device 1 which includes a respective semiconductor body 2, having a cavity 4 extending therewithin. The MEMS device 1 comprises a cantilever 5, which has an end integral with the semiconductor body 2 and includes a respective semiconductive portion 6. An oxide layer 7, which is typically formed by thermal oxide, extends above the semiconductor body 2 and the semiconductive portion 6; a transducer 8, which is for example a pressure transducer, extends above the portion of oxide layer 7 that overlies the semiconductive portion 6 and, although not shown, may include, among other things, a pressure deformable membrane, which is coupled to the cantilever 5 so as to form a corresponding sensing cavity, and corresponding electrodes.

In practice, the fact of arranging the transducer 8 above the cantilever 5 allows reducing the impact on the transducer 8 of the residual mechanical stresses which generate during the packaging process of the MEMS device 1 or which generate during the step of soldering the package. However, due to the compressive behavior of the oxide layer 7, the cantilever 5 tends to bend downwards, i.e., towards the cavity 4, as qualitatively shown in FIG. 1. This deformation of the cantilever 5 is undesired, since it may cause generation of an offset in the transducer 8 and may also lead the non-constrained end of the cantilever 5 to contact the bottom of the cavity 4, in which case the (undesired) stiction of the non-constrained end of the cantilever 5 to the bottom of the cavity 4 may occur.

In general, the deformation of the cantilever 5 and the resulting drawbacks may also occur in case, above the semiconductive portion 6 of the cantilever 5, a set of layers is present including at least one layer with compressive behavior, not necessarily in direct contact with the semiconductive portion 6 of the cantilever 5.

The aim of the present disclosure is therefore to provide a MEMS device which at least partially overcomes the drawbacks of the prior art.

### BRIEF SUMMARY

According to embodiments of the present disclosure, a MEMS device and a manufacturing process are provided. A MEMS device can be summarized as including: a fixed body delimiting a cavity; a suspended structure extending cantilevered from the fixed body, above the cavity, and including a suspended semiconductive region; and a transducer above the suspended structure, and wherein the suspended structure further includes a compensation region of thermal oxide, which extends below the suspended semiconductive region.

### BRIEF DESCRIPTION OF THE SEVERAL VIEWS OF THE DRAWINGS

For a better understanding of embodiments of the present disclosure, embodiments are now described, by way of non-limiting example, with reference to the attached drawings, wherein:

FIG. 1 schematically shows a cross-section of a MEMS device;

FIG. 2 schematically shows a cross-section of an embodiment of the present MEMS device;

FIG. 3 schematically shows a top view with portions removed of the MEMS device shown in FIG. 2;

FIGS. 4-9 schematically show cross-sections of the MEMS device shown in FIG. 2, during successive steps of a manufacturing process;

FIGS. 10-15 schematically show cross-sections of an alternative embodiment of the MEMS device shown in FIG. 2, during successive steps of a manufacturing process;

FIGS. 16-17 schematically show cross-sections of an alternative embodiment of the MEMS device shown in FIG. 2, during successive steps of a manufacturing process;

FIGS. 18-21 schematically show cross-sections of an alternative embodiment of the MEMS device shown in FIG. 2, during successive steps of a manufacturing process; and

FIGS. 22-23 schematically show cross-sections of an alternative embodiment of the MEMS device shown in FIG. 2, during successive steps of a manufacturing process.

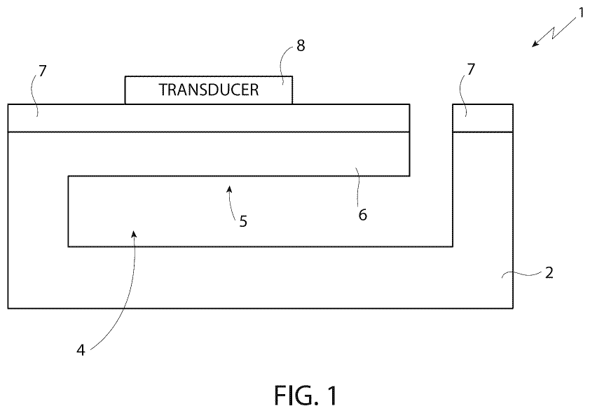

### DETAILED DESCRIPTION

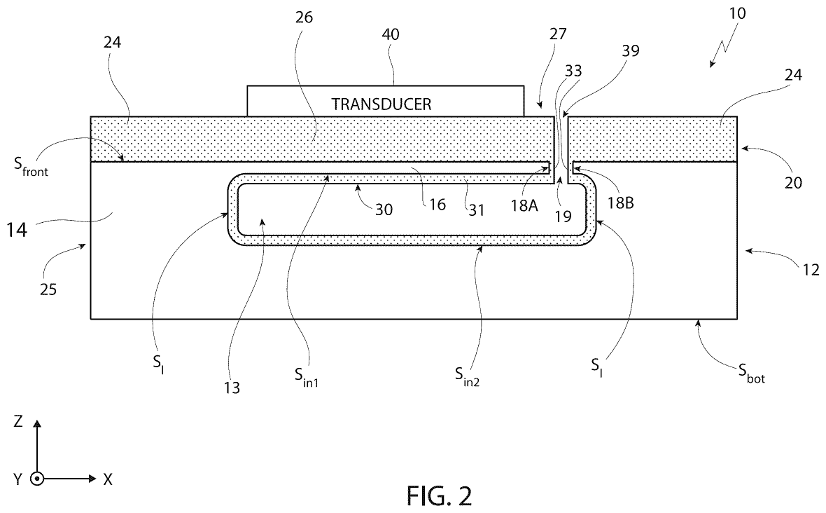

FIG. 2 shows an orthogonal reference system XYZ and a MEMS device 10, which comprises a semiconductor body 12, formed for example by silicon.

The semiconductor body 12 may comprise for example a semiconductor substrate and one or more epitaxial layers (not shown individually in FIG. 2). The semiconductor body 12 is delimited upwardly by a front surface S_{front} and is delimited downwardly by a bottom surface S_{bot}. As a first approximation, the front surface S_{front} and the bottom surface S_{bot} are parallel to the XY plane.

The semiconductor body 12 houses a cavity 13 and forms a fixed semiconductive region 14 and a suspended semiconductive region 16, which extends cantilevered from the fixed semiconductive region 14. In particular, the fixed semiconductive region 14 delimits the cavity 13 downwardly and laterally; the suspended semiconductive region 16 delimits the cavity 13 upwardly.

In greater detail, the fixed semiconductive region 14 and the suspended semiconductive region 16 are delimited upwardly by the front surface S_{front}. The suspended semiconductive region 16 has a first end, which is fixed to the fixed semiconductive region 14, and a second end, which is free; furthermore, the suspended semiconductive region 16 is delimited downwardly by a first internal surface Sᵢₙ₁, which delimits the cavity 13 upwardly. The cavity 13 is delimited laterally by a lateral surface Sₗ and is delimited downwardly by a second internal surface Sᵢₙ₂, which are formed by the fixed semiconductive region 14.

In even greater detail, the suspended semiconductive region 16 is delimited laterally by a first trench portion 19, which faces, upwardly, the front surface S_{front} and also faces, downwardly, the first internal surface Sᵢₙ₁, so as to communicate with the underlying cavity 13.

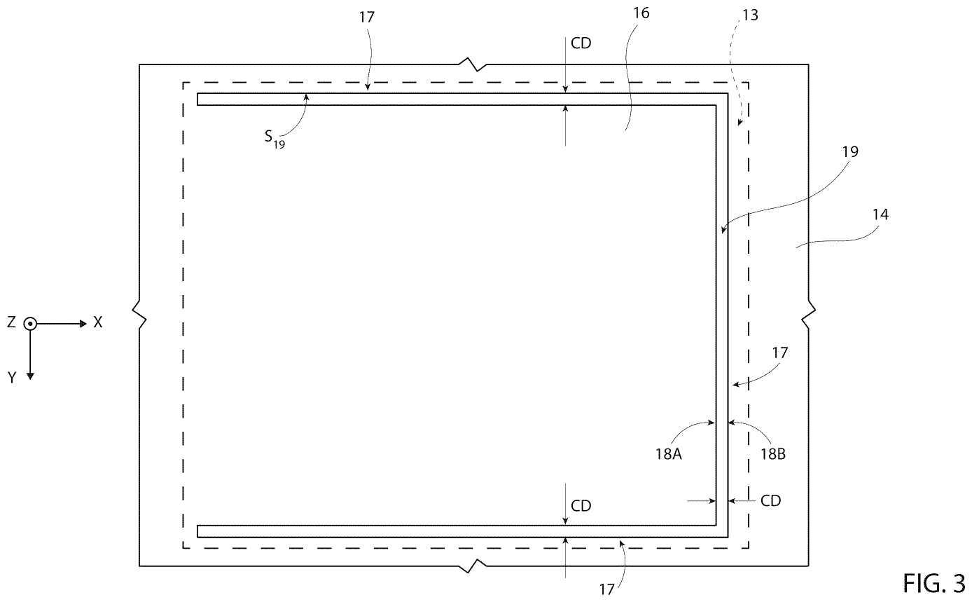

As shown in FIG. 3, wherein the cavity 13 is shown with a dashed line, in top view the first trench portion 19 has an elongated shape, for example a ‘C’ shape, with approximately a constant width. Consequently, the first trench portion 19 is delimited laterally by three pairs 17 of lateral walls, which define a lateral trench surface S₁₉. In particular, each pair 17 of lateral walls comprises a respective first wall, formed by the suspended semiconductive region 16, and a respective second wall, formed by the fixed semiconductive region 14 and facing the corresponding first wall, the first and the second walls being approximately parallel to each other and spaced by a distance CD, as visible in FIG. 3, wherein for brevity only the first and the second walls arranged parallel to the XY plane have been indicated (by 18A and 18B, respectively). As a first approximation, the distance CD is the same for the three pairs 17 of lateral walls and may for example be comprised in the range 0.2 μm-2 μm (boundaries included); however, the distance CD may also be variable according to the pair of lateral walls.

The MEMS device 10 further comprises a front dielectric layer 20, which is formed by thermal oxide and extends above the front surface S_{front}. The front dielectric layer 20 includes a first portion 24, which overlies the fixed semiconductive region 14, in direct contact, and a second portion 26, which overlies the suspended semiconductive region 16, in direct contact. The first and the second portions 24, 26 are separated by a second trench portion 39, which extends through the front dielectric layer 20 and communicates with the underlying first trench portion 19, forming a single trench therewith; as a first approximation, in top view the second trench portion 39 may have the same ‘C’ shape as the first trench portion 19, in such a way that the aforementioned trench also has approximatively a ‘C’ shape.

Purely by way of example, the front dielectric layer 20 may have a thickness comprised in the range 0.5 μm-3.2 μm (boundaries included).

The first portion 24 of the front dielectric layer 20 and the fixed semiconductive region 14 form a fixed structure 25; the second portion 26 of the front dielectric layer 20 and the suspended semiconductive region 16 form a suspended structure 27, which is delimited laterally by the first and the second trench portions 19, 39 and extends cantilevered from the fixed structure 25, being fixed thereto, so as to overlay the cavity 13.

The MEMS device 10 further comprises an internal dielectric layer 30, which conformally coats the cavity 13, therefore coating the cavity 13 without filling it. In particular, the internal dielectric layer 30 coats the lateral surface Sₗ and the first and the second internal surfaces Sᵢₙ₁, Sᵢₙ₂. In the following, reference is made to a compensation portion 31 to indicate the portion of the internal dielectric layer 30 which coats the first internal surface Sᵢₙ₁. The compensation portion 31 also forms the suspended structure 27; the compensation portion 31 is a mechanical tension compensation portion.

As explained in greater detail below, as a first approximation the internal dielectric layer 30 has a thickness equal to half the distance CD.

The MEMS device 10 comprises a coating region 33, which is formed by thermal oxide and coats the lateral trench surface S₁₉, so as to contact upwardly and downwardly, respectively, with the front dielectric layer 20 and the internal dielectric layer 30, forming a single thermal oxide region therewith.

The MEMS device 10 further comprises a transducer 40, which is arranged above the second portion 26 of the front dielectric layer 20.

Purely by way of example, the transducer 40 is a capacitive pressure transducer and, although not shown, includes a respective pressure deformable membrane and respective electrodes, in such a way that, in use, the transducer 40 is configured to generate an electrical signal indicative of pressure. In any case, the type of transducer is irrelevant for the purposes of the present disclosure.

The suspended semiconductive region 16 is interposed between the second portion 26 of the front dielectric layer 20 and the compensation portion 31 of the internal dielectric layer 30, which, as explained, are both formed by thermal oxide and, therefore, have a same compressive behavior. Therefore, since the second portion 26 of the front dielectric layer 20 and the compensation portion 31 of the internal dielectric layer 30 extend on opposite faces of the suspended semiconductive region 16, a compensation of the tensions which act on the suspended semiconductive region 16 is obtained, reducing the deformation of the suspended semiconductive region 16 and, more generally, of the suspended structure 27. In this manner, possible offsets that might affect the transducer 40, in case the suspended structure 27 were bent, are reduced.

The MEMS device 10 may be manufactured by the manufacturing process described hereinbelow, from a semiconductive wafer 100, which is intended to form the semiconductor body 12 and is delimited by the front surface S_{front} and the bottom surface S_{bot}.

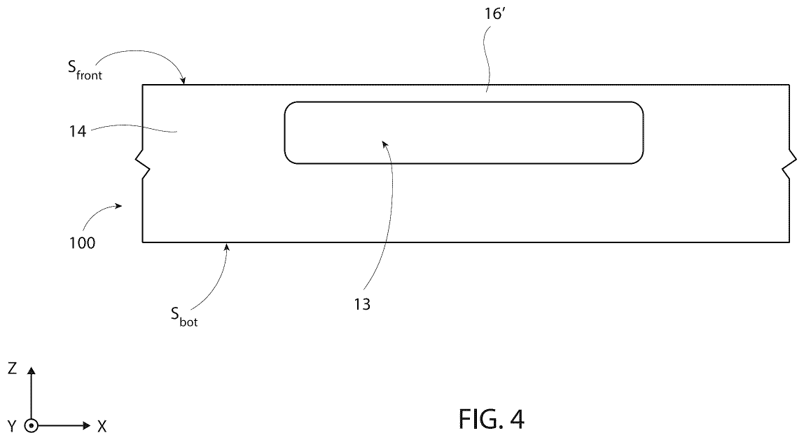

Initially, as shown in FIG. 4, the cavity 13 is formed, in a per se known manner. Initially the cavity 13 is of buried type, therefore it extends at a distance from the front surface S_{front} and from the bottom surface S_{bot}. In this manner, the semiconductive wafer 100 forms the fixed semiconductive region 14 and a temporary semiconductive region 16′, which closes the cavity 13 upwardly and is intended to form the suspended semiconductive region 16.

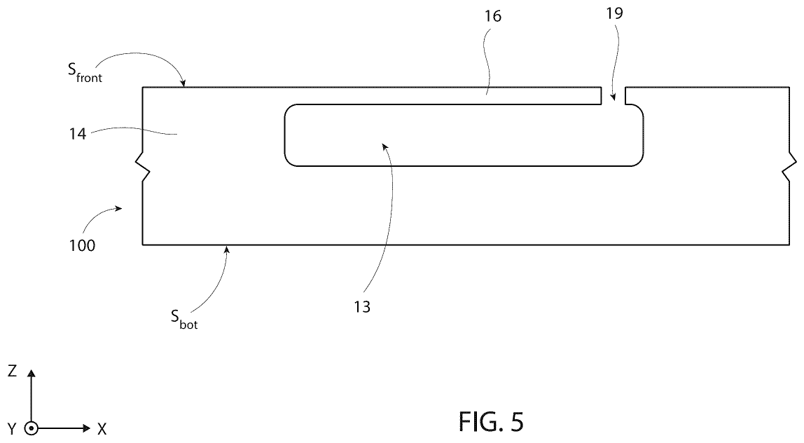

Subsequently, as shown in FIG. 5, an etching process (for example, of dry or wet type) is performed, so as to selectively remove a portion of the temporary semiconductive region 16′ and form the first trench portion 19, which communicates with the cavity 13 downwardly. The remaining portion of the temporary semiconductive region 16′ forms the suspended semiconductive region 16.

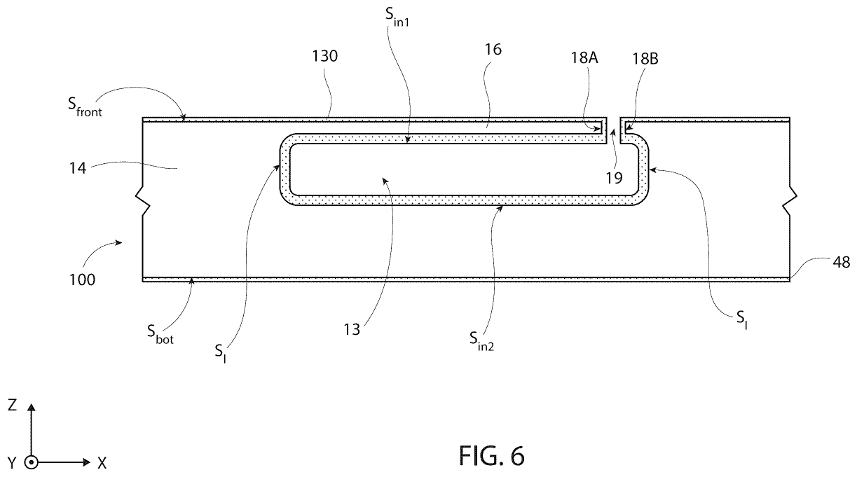

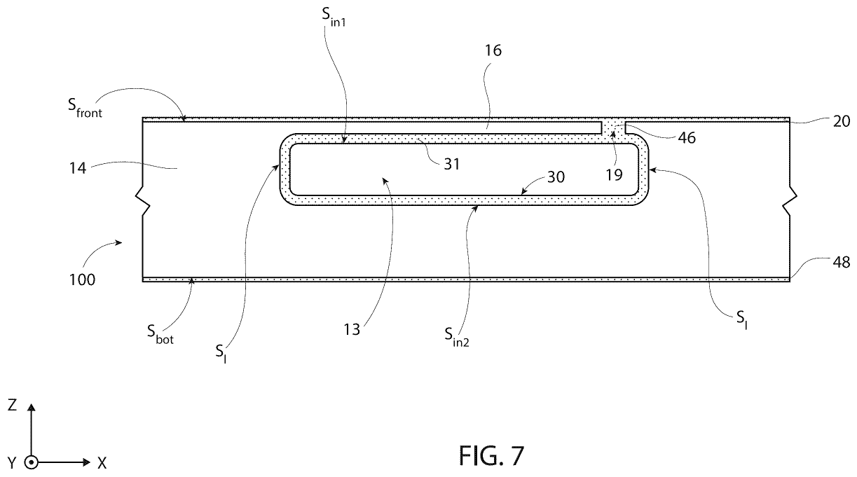

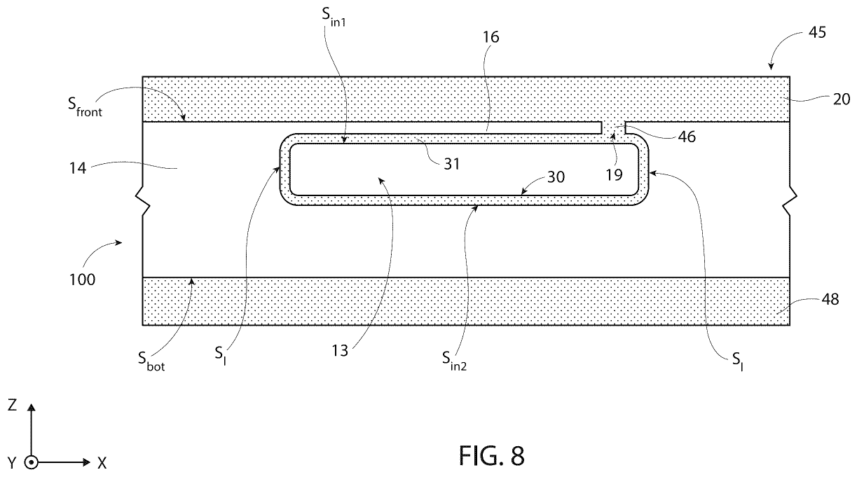

Successively, as shown in FIGS. 6, 7 and 8, a thermal oxidation process is performed; in particular, FIG. 6 refers to an initial step of the thermal oxidation process, while FIG. 7 refers to an intermediate step of the thermal oxidation process; FIG. 8 refers to a terminal step of the thermal oxidation process. For simplicity it is assumed that, as a first approximation, the shape of the first trench portion 19 does not change during the thermal oxidation process, i.e., the changes in the shape of the first trench portion 19 (in particular, the modifications of the lateral walls) caused by this oxidation are neglected.

In greater detail, as shown in FIG. 6, initially the manufacturing process causes the formation of a preliminary layer 130 of thermal oxide, which coats the lateral surface Sₗ and the first and the second internal surfaces Sᵢₙ₁, Sᵢₙ₂ of the cavity 13, and the front surface S_{front}; furthermore, the preliminary layer 130 coats the lateral trench surface S₁₉, i.e., the pairs 17 of lateral walls of the first trench portion 19, without completely filling the first trench portion 19, i.e., without closing the first trench portion 19, which forms an opening arranged facing the cavity 13. The preliminary layer 130 has a substantially uniform thickness, which increases over time. In fact, the portions of preliminary layer 130 that coat the front surface S_{front} and the pairs 17 of lateral walls of the first trench portion 19 are exposed to the reagent used in the thermal oxidation process, therefore they gradually increase in thickness; since the first trench portion 19 is not closed, the reagent may continue to enter the cavity 13, allowing the gradual increase in thickness also of the portions of the preliminary layer 130 that coat the lateral surface Sₗ and the first and the second internal surfaces Sᵢₙ₁, Sᵢₙ₂ of the cavity 13.

When the thickness of the preliminary layer 130 becomes approximately equal to half the distance CD, it occurs that, as shown in FIG. 7, the portions of preliminary layer 130 that coat the pairs 17 of lateral walls of the first trench portion 19 obstruct the first trench portion 19, sealing the cavity 13. Since the reagent can no longer access the cavity 13, the thermal oxidation process, and therefore the increase in thickness of the preliminary layer 130, stops within the cavity 13, while continues outside, and in particular, above the front surface S_{front}. In these conditions, the portions of preliminary layer 130 that coat the lateral surface S₁ and the first and the second internal surfaces Sᵢₙ₁, Sᵢₙ₂ of the cavity 13 form the internal dielectric layer 30; the portions of preliminary layer 130 that coat the front surface S_{front} form the front dielectric layer 20; furthermore, the portions of preliminary layer 130 that coat the pairs 17 of lateral walls of the first trench portion 19 form a top closing region 46, which precisely fills the first trench portion 19, sealing it.

Successively, the thermal oxidation process continues, above the front surface S_{front}, with a resulting increase in thickness of the front dielectric layer 20, as shown in FIG. 8. Conversely, the internal dielectric layer 30 does not undergo modifications.

At the end of the thermal oxidation process, a dielectric structure 45 of thermal oxide is present, which comprises the front dielectric layer 20, the internal dielectric layer 30 and the top closing region 46. Although not previously described, during the thermal oxidation process, a temporary layer 48 of thermal oxide, whose thickness gradually increases over time during the thermal oxidation process, forms below the bottom surface S_{bot}.

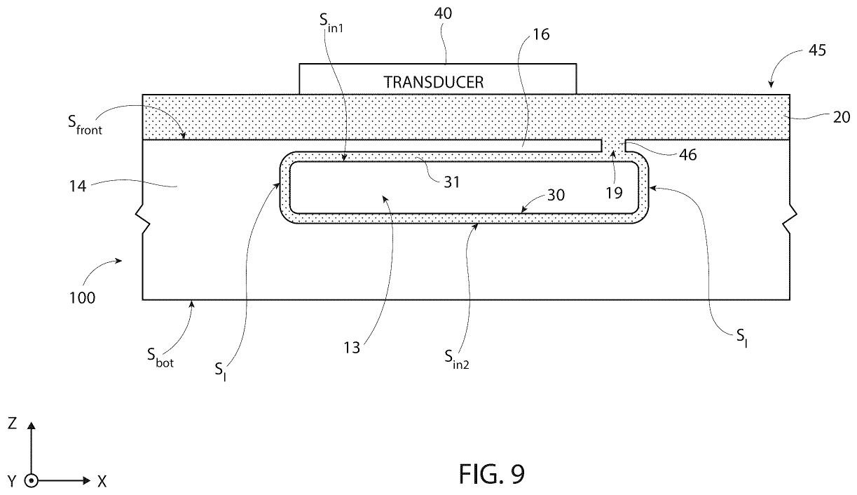

Subsequently, as shown in FIG. 9, the temporary layer 48 is removed, in a per se known manner. Furthermore, the transducer 40 is formed in a per se known manner; forming the transducer 40 that may include forming further regions/layers, which are not shown.

Finally, to obtain the MEMS device 10 shown in FIG. 2, an etching (for example, of wet or dry type) is performed, so as to selectively remove a portion of the front dielectric layer 20 (thus forming the second trench portion 39) and an underlying portion of the top closing region 46, thanks to the use of a mask (not shown). In this manner, the first and the second portions 24, 26 of the front dielectric layer 20 are defined and the release of the suspended structure 27 is obtained. The remaining portion of the top closing region 46 forms the coating region 33. Although not shown, however, variations (not shown) are possible, wherein the mask is such that the top closing region 46 is entirely removed, so as to expose the pairs 17 of lateral walls of the trench 19; in this case, the etching process is defined by the trench 19.

The manufacturing process may therefore proceed in a per se known manner, for example by performing dicing operations on the semiconductive wafer 100, which are not further described.

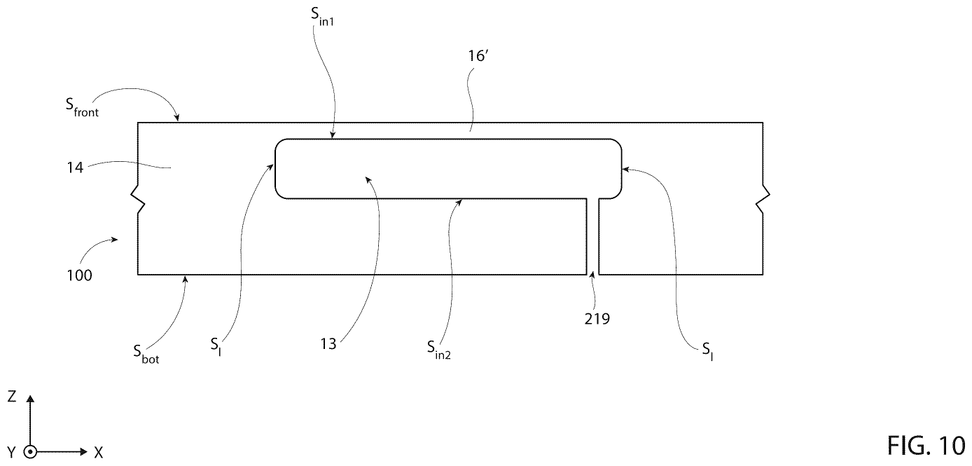

According to a variation of the manufacturing process, following the formation of the cavity 13, of buried type and delimited upwardly by the temporary semiconductive region 16′, a hole 219 is formed, as shown in FIG. 10. Purely by way of example, the hole 219 may have a cylindrical section and extends vertically between the second internal surface Sᵢₙ₂ and the bottom surface S_{bot}.

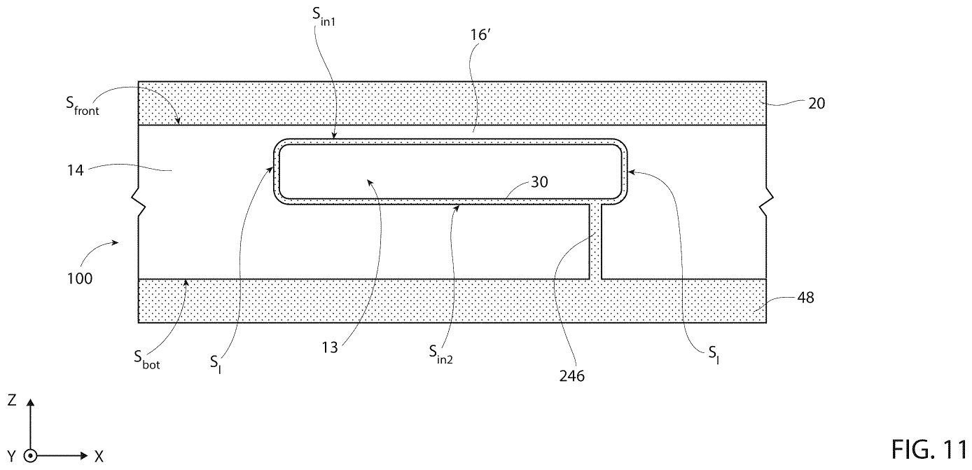

Subsequently, as shown in FIG. 11, a thermal oxidation process is performed, in the same manner as described with reference to FIGS. 6-8, in such a way as to form the internal dielectric layer 30 and a bottom closing region 246, which is formed by thermal oxide and fills the hole 219, so as to seal the cavity 13. Although not shown in detail, even in this case the thermal oxidation process causes the formation, within the cavity 13 and the hole 219, of a thermal oxide preliminary layer, whose thickness increases over time, up to obstructing the hole 219; the closing of the hole 219 occurs before the end of the thermal oxidation process. Consequently, the thickness of the internal dielectric layer 30 depends on the shape of the hole 219; for example, in case the hole 219 has an invariant section for translations parallel to the Z-axis, the thickness of the internal dielectric layer 30 depends on the shape of the section of the hole 219.

During the thermal oxidation process, the formation of the front dielectric layer 20 and the temporary layer 48 also occurs.

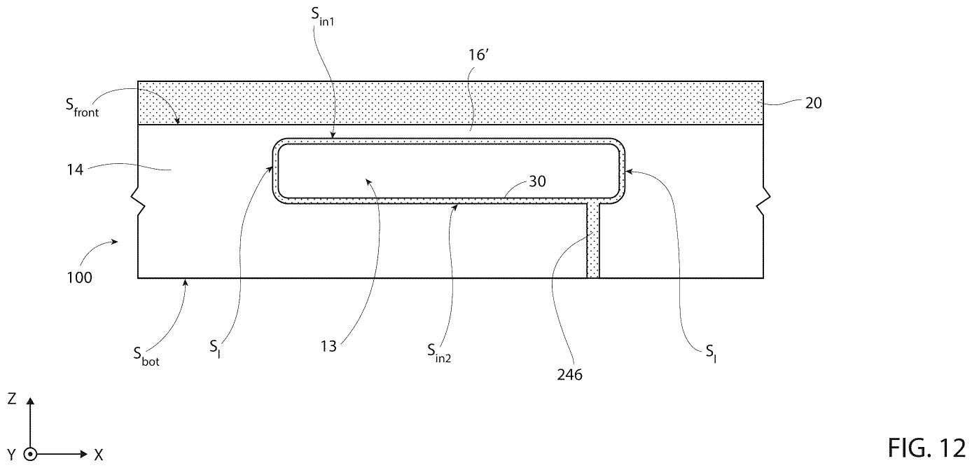

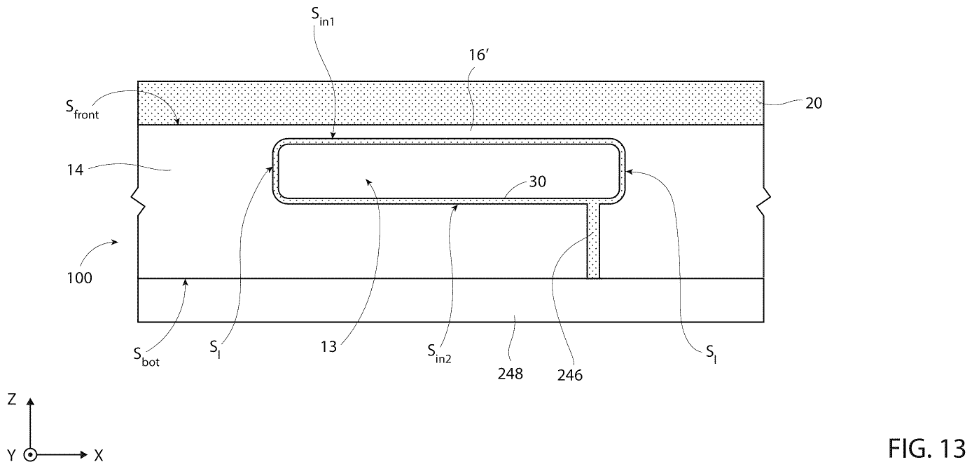

Subsequently, as shown in FIG. 12, the temporary layer 48 is removed. Successively, optionally, an epitaxial growth of semiconductor material may be carried out from the bottom surface S_{bot}, as shown in FIG. 13. In this manner, a bottom epitaxial region 248 of semiconductor material, which allows the thickness of the semiconductive wafer 100 to be increased, if desired, is formed below the bottom surface S_{bot}; in any case, the bottom epitaxial region 248 is optional.

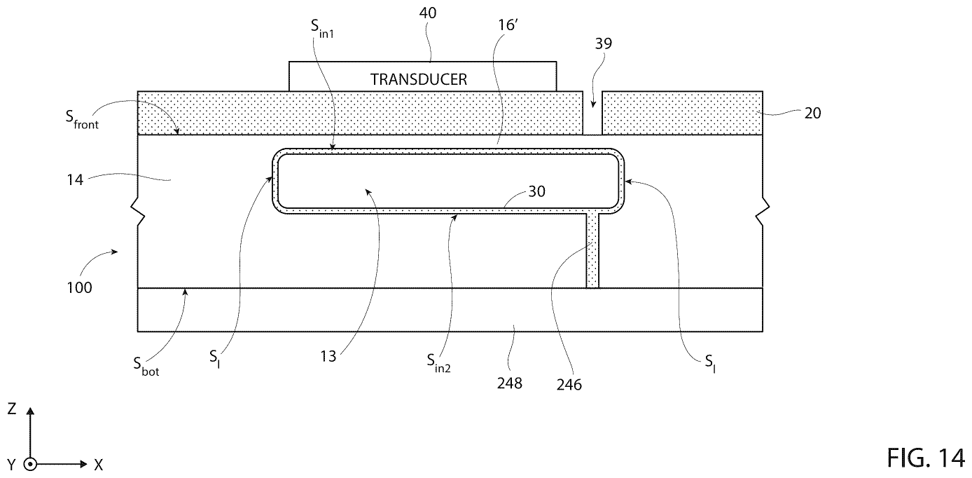

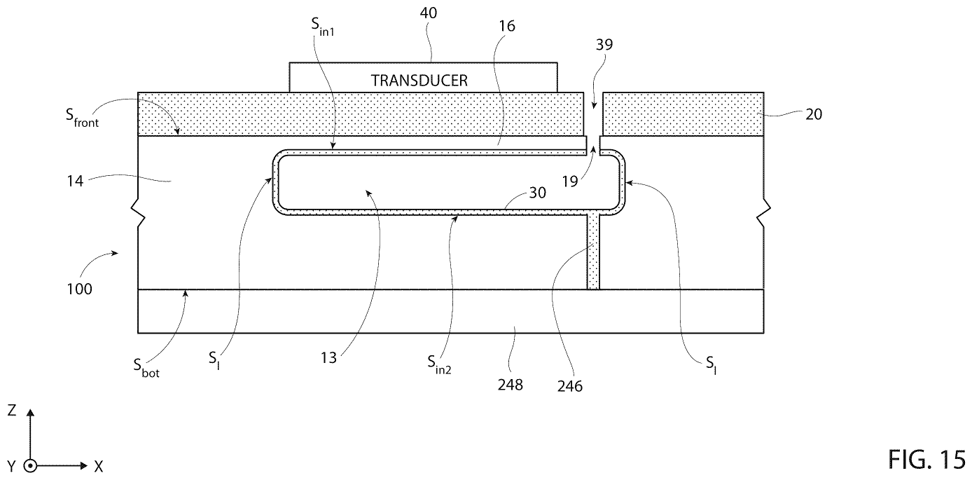

Subsequently, the manufacturing process proceeds with the formation of the transducer 40 on a portion of the front dielectric layer 20 that overlies the temporary semiconductive region 16′ and a successive etching process, which selectively removes a portion of the top dielectric layer 20, so as to form the second trench portion 39 and expose a part of the temporary semiconductive region 16′, as shown in FIG. 14. Subsequently, an etching process (for example, of dry or wet type) is performed to selectively remove a portion of the exposed part of the temporary semiconductive region 16′, so as to form the first trench portion 19, and a part of the internal dielectric layer 30 that extends below the first trench portion 19, so as to release the suspended structure 27, as shown in FIG. 15. In this case, the coating region 33 is absent.

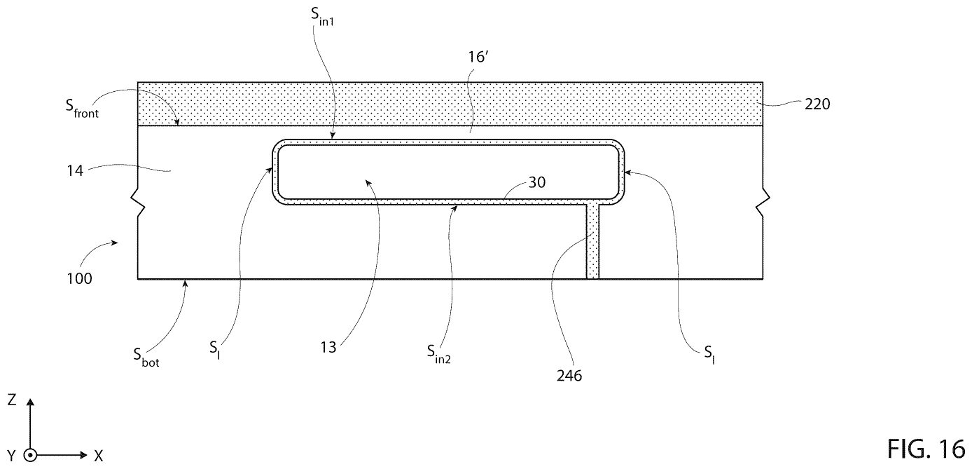

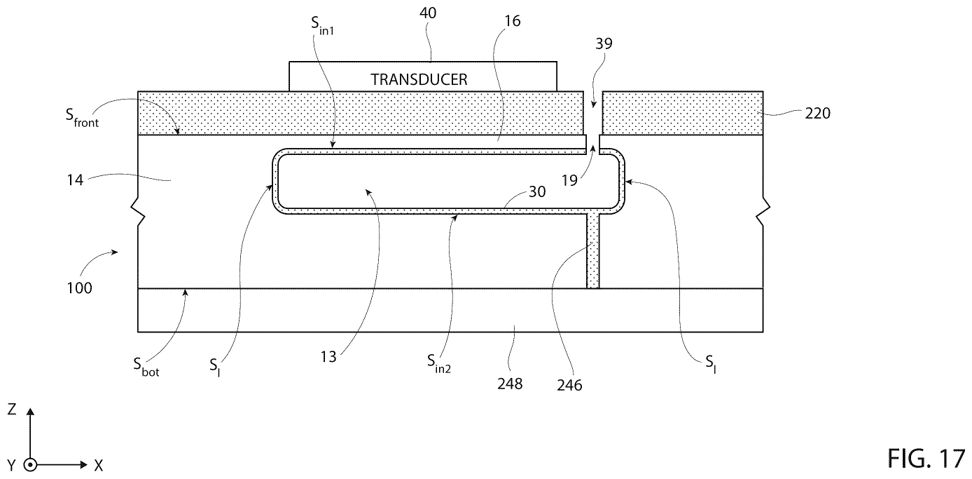

According to a variation, following the operations shown in FIG. 12, the front dielectric layer 20 may be removed and successively an alternative dielectric layer 220, formed for example of silicon nitride, may be formed above the front surface S_{front}, as shown in FIG. 16. In this case, the manufacturing process may then proceed as described with reference to FIGS. 13-15, but the transducer 40 is formed on the alternative dielectric layer 220, as shown in FIG. 17.

The alternative dielectric layer 220 has a tensile behavior, therefore it would per se tend to cause the suspended structure 27 to bend upwards. However, the transducer 40 may include one or more respective layers (not shown) with compressive behavior; consequently, the compensation portion 31 of the internal dielectric layer 30 may be sized so as to compensate the overall behavior of the layers present above the suspended semiconductive region 16, including any layers that form the transducer 40 and are not in direct contact with the suspended semiconductive region 16.

In general, even in the case of the manufacturing process described with reference to FIGS. 4-9, in lieu of the front dielectric layer 20 or above the front dielectric layer 20, a layer (not shown) formed by a dielectric different from thermal oxide, which may have tensile behavior, may be present.

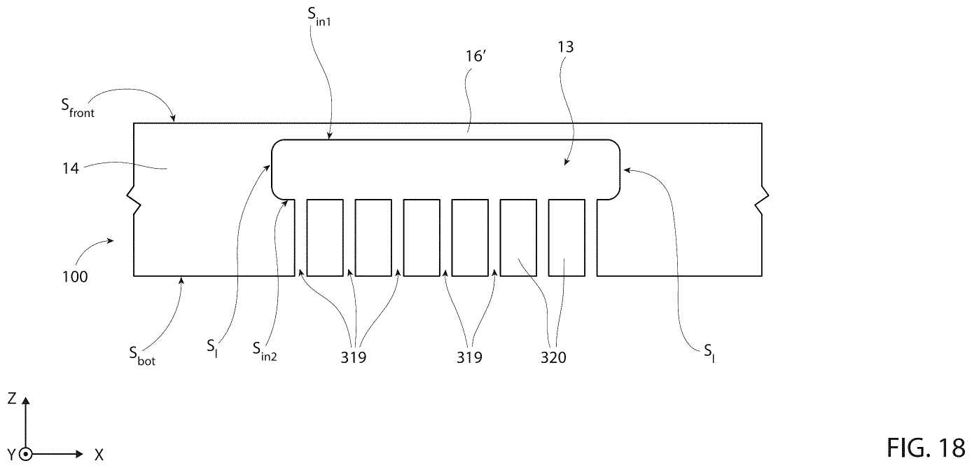

According to a further variation, the manufacturing process envisages, after forming the cavity 13 of buried type, forming a plurality of holes 319, which extend between the second internal surface Sᵢₙ₂ and the bottom surface S_{bot}, as shown in FIG. 18. Pairs of adjacent holes 319 laterally delimit corresponding semiconductive pillars 320.

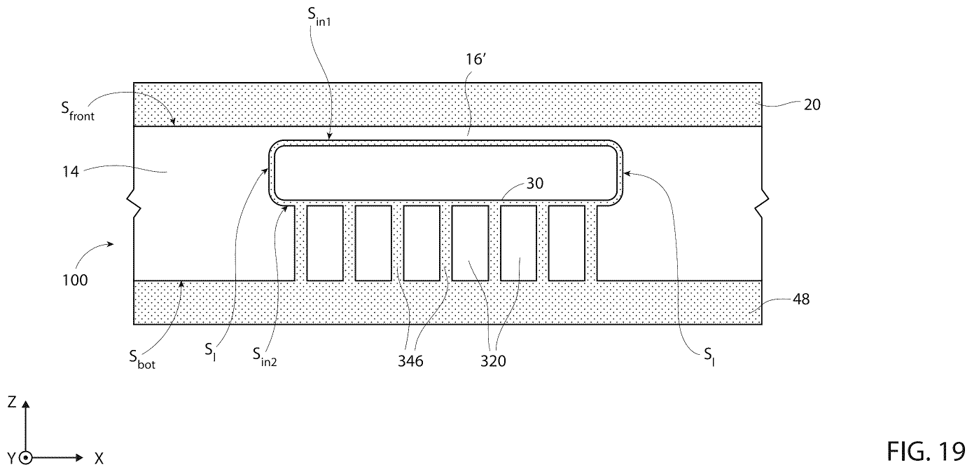

Subsequently, as shown in FIG. 19, a thermal oxidation process is performed, as already described with reference to FIG. 11. In this manner, the internal dielectric layer 30 and a plurality of bottom closing regions 346 are formed. Each bottom closing region 346 is formed by thermal oxide and fills a corresponding hole 319. The cavity 13 is thus sealed. The thermal oxidation process also causes the formation of the front dielectric layer 20 and the temporary layer 48.

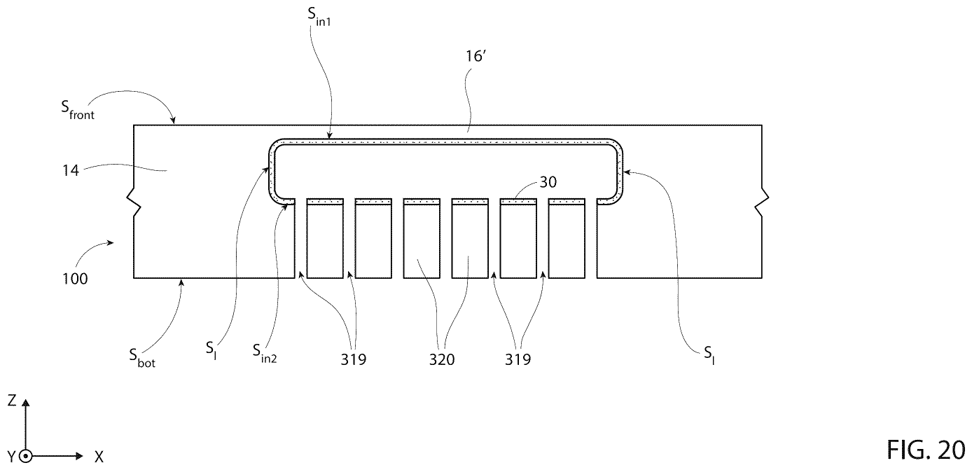

Subsequently, as shown in FIG. 20, the front dielectric layer 20, the temporary layer 48 and the bottom closing regions 346 are removed. In practice, the holes 319 are opened again and also extend through the portion of internal dielectric layer 30 that coats the second internal surface Sᵢₙ₂, forming corresponding openings of the cavity 13.

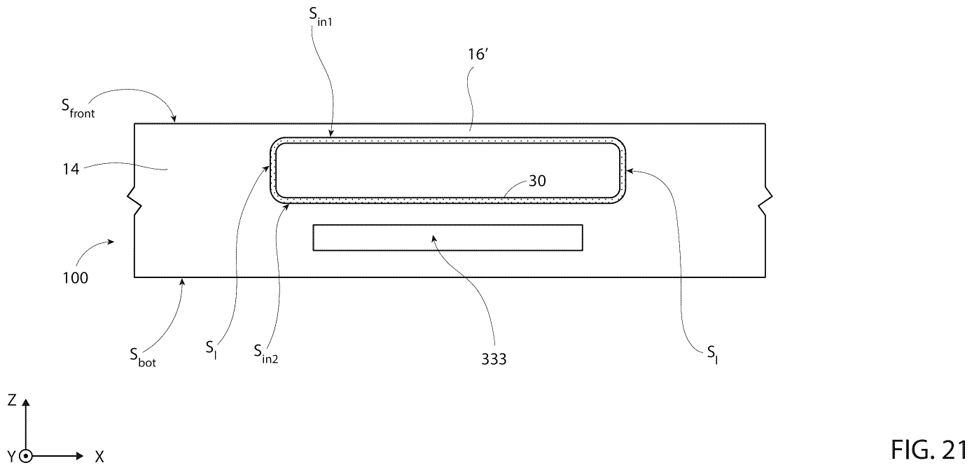

Successively, as shown in FIG. 21, a thermal treatment is performed in a hydrogen (H₂) environment, which causes a redistribution of the material which forms the semiconductive pillars 320, in such a way that the openings of the cavity 13 close and the internal dielectric layer 30 completely coats again the second internal surface Sᵢₙ₂; between the cavity 13 and the bottom surface S_{bot} an additional cavity 333, of buried type, is formed which, purely by way of example, may allow for example a differential-type pressure transduction to be carried out.

Subsequently, the manufacturing process may continue for example as described with reference to FIG. 16, therefore with the formation of the alternative dielectric layer 220 and with the subsequent operations previously described, but without forming the bottom epitaxial region 248. Furthermore, in case (not shown), after the operations shown in FIG. 19, only the temporary layer 48 and the bottom closing regions 346 were removed (i.e., leaving the front dielectric layer 20), the manufacturing process might proceed as described with reference to FIGS. 14 and 15.

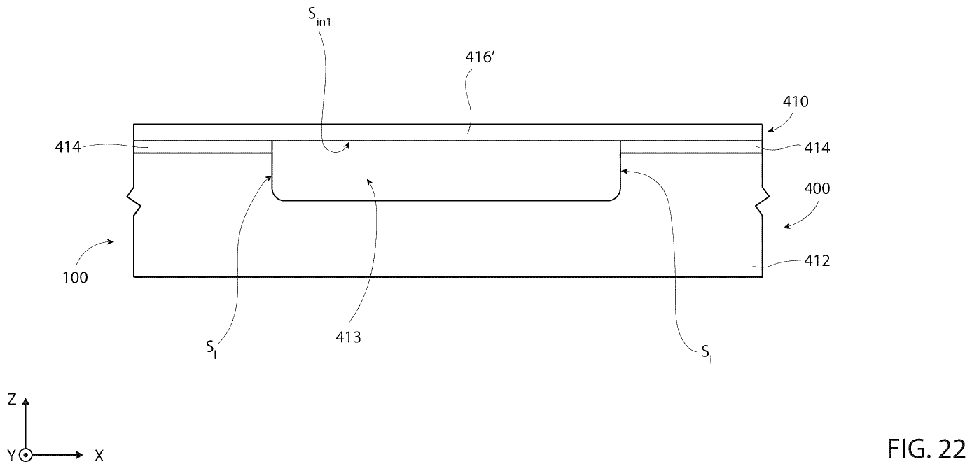

According to a further variation of the manufacturing process, as shown in FIG. 22, the cavity (here indicated by 413) may be formed in a “silicon-on-insulator” structure 400, which includes a top semiconductive substrate 410 and a bottom semiconductive substrate 412, which are formed for example by silicon and are coupled by interposition of an insulating layer 414 of silicon oxide. In this case, the cavity 413 is delimited upwardly by a part 416′ of the top semiconductive substrate 410, which is delimited downwardly by the first internal surface Sᵢₙ₁; the second internal surface Sᵢₙ₂ is formed by the bottom semiconductive substrate 412. Furthermore, a top portion of the lateral surface S₁ is formed by the insulating layer 414; a bottom portion of the lateral surface S₁ is formed by the bottom semiconductive substrate 412.

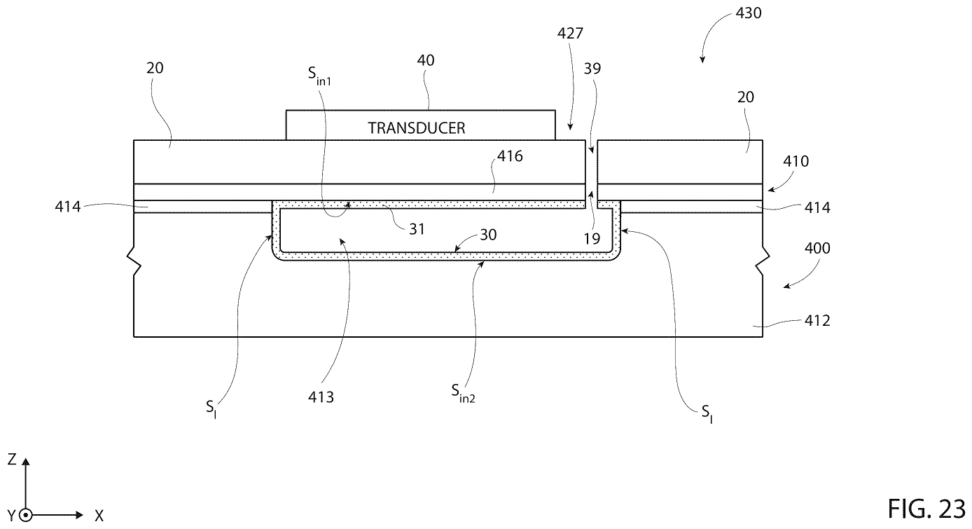

In this case, the manufacturing process may proceed as described with reference to FIGS. 5-9; the part 416′ of the top semiconductive substrate 410 performs the function previously performed by the temporary semiconductive region 16′. In this manner, the MEMS device 430 shown in FIG. 23 is obtained, wherein the front dielectric layer (indicated again by 20 and traversed by the second trench portion 39) extends on the top semiconductive substrate 410; the first trench portion (indicated again by 19) extends through the top semiconductive substrate 410 and delimits the suspended semiconductive region (here indicated by 416), which is formed by a residual portion of the part 416′ of the top semiconductive substrate 410; the internal dielectric layer (indicated again by 30) coats the cavity 413; the compensation portion (indicated again by 31) extends below the suspended semiconductive region 416. The suspended structure (here indicated by 427) is formed by the suspended semiconductive region 416, the compensation portion 31 and the portion of front dielectric layer 20 overlying the suspended semiconductive region 416.

The advantages that the present solution affords are clear from the preceding description.

In particular, the present solution allows reducing the bending of the suspended structure which extends cantilevered and supports the transducer, resulting in performance improvement of the latter. Furthermore, the present solution allows setting the thickness of the thermal oxide region which extends below the suspended semiconductive region, so as to adapt the compressive action of this thermal oxide region as a function of the composition of the layers that extend above the suspended semiconductive region. In this regard, as previously mentioned, the compressive layer arranged above the suspended semiconductive region may form part of the transducer or in any case may not be in direct contact with the suspended semiconductive region.

In addition, the present solution is inexpensive and may be easily integrated into a process flow of a known type.

Finally, it is clear that modifications and variations may be made to the present MEMS device and the manufacturing process, without departing from the scope of the present disclosure, as defined in the attached claims.

For example, in general the transducer may be of any type. The transducer may be suitable for being controlled (e.g., electrically controlled) in order to transduce a control signal into a corresponding transduced signal (e.g., an acoustic signal).

Referring for simplicity to the embodiment shown in FIG. 2 (but the same considerations also apply to the other embodiments), the shapes of the first and the second trench portions 19, 39 may vary with respect to what has been described; more generally, the relationship between the thickness of the internal dielectric layer 30 and the shape of the first trench portion 19 may vary with respect to what has been described.

As regards the embodiment shown in FIG. 2, the front dielectric layer 20 may be formed by an oxide other than a thermal oxide, such as for example, a deposited oxide.

Finally, as previously mentioned, the number and the type of layers arranged above the suspended semiconductive region may differ with respect to what has been described.

A MEMS device may be summarized as including: a fixed body (14;400) delimiting a cavity (13;413); a suspended structure (27;427) extending cantilevered from the fixed body, above the cavity, and including a suspended semiconductive region (16;416); and a transducer (40) arranged above the suspended structure, and wherein the suspended structure further includes a compensation region (31) of thermal oxide, which extends below the suspended semiconductive region.

The MEMS device may further include at least one compressive region (20) arranged above the suspended semiconductive region (16;416).

The compressive region (20) may include a front dielectric layer (20) of thermal oxide, arranged above the suspended semiconductive region (16;416).

The front dielectric layer (20) may contact the suspended semiconductive region (16; 416), and the transducer (40) may be arranged above the front dielectric layer.

The MEMS device may include an internal dielectric layer (30) of thermal oxide, which coats the cavity (13) and forms the compensation region (31).

A process for manufacturing a MEMS device (10;430), may be summarized as including: forming a fixed body (14;400) delimiting a cavity (13;413); forming a suspended structure (27;427) extending cantilevered from the fixed body, above the cavity, and including a suspended semiconductive region (16;416); and forming a transducer (40) arranged above the suspended structure, and wherein forming the suspended structure includes forming a compensation region (31) of thermal oxide, which extends below the suspended semiconductive region.

The manufacturing process may include forming at least one compressive region (20) arranged above the suspended semiconductive region (16;416).

Forming at least one compressive region (20) may include forming a front dielectric layer (20) of thermal oxide, arranged above the suspended semiconductive region (16;416).

Forming a fixed body (12) may include forming a semiconductor body (12) delimited by a front surface (S_{front}) and a bottom surface (S_{bot}); said manufacturing process further including: forming the cavity (13) so that it is buried into the semiconductor body; forming at least one opening (19;219) which extends into the semiconductor body, between the cavity and one of the front surface and the bottom surface; and performing a thermal oxidation process, so as to coat the cavity with an internal dielectric layer (30) of thermal oxide, which forms the compensation region (31), and wherein forming the suspended structure includes releasing the suspended structure following the formation of the internal dielectric layer.

The manufacturing process may include forming the front dielectric layer (20) by said thermal oxidation process.

The manufacturing process may include, by the thermal oxidation process: increasing the thickness of the internal dielectric layer (30); and causing the formation of a closing region (46;246) of thermal oxide which closes the opening (19;219), sealing the cavity (13), so as to stop the increase in thickness of the internal dielectric layer (30) before the end of the thermal oxidation process, in such a way that the thickness of the internal dielectric layer (30) depends on the shape of the opening.

Forming at least one opening (19;219) may include forming, after forming the cavity (13) and before performing the thermal oxidation process, a plurality of openings (319) which extend between the cavity (13) and the bottom surface (S_{bot}), in such a way that the openings delimit a plurality of pillar semiconductive regions (320); and the execution of the thermal oxidation process may cause the formation, in each opening (319), of a corresponding closing region (346) of thermal oxide, so as to seal the cavity; said manufacturing process further including: selectively removing the closing regions; and performing a thermal treatment so as to cause the formation, from the pillar semiconductive regions (320), of an additional cavity (333), which is of buried type and extends between the cavity and the bottom surface (S_{bot}).

Forming a fixed body (12) may include forming a structure (400) including an insulating layer (414) and a top semiconductive substrate (410) and a bottom semiconductive substrate (412), which are coupled by interposition of the insulating layer; said manufacturing process further including: forming the cavity (413) so that it is delimited upwardly by a part (416′) of the top semiconductive substrate and is delimited laterally by portions of the insulating layer and the bottom semiconductive substrate; forming a trench (19) which extends through the part of the top semiconductive substrate; and performing a thermal oxidation process, so as to coat the cavity with an internal dielectric layer (30) of thermal oxide, which forms the compensation region (31).

A device is summarized as including: a structure having a first surface and a second surface opposite the first surface; a first substrate on the first surface of the structure and a second substrate on the second surface of the structure; an insulating layer interposed between the first substrate and the second substrate, the insulating layer coupling the first and second substrate together; a cavity in the structure delimited upwardly by a first portion of the first substrate; a suspended structured extending cantilevered from the structure and comprising a suspended semiconductive region; and a transducer arranged on the suspended structure above the cavity.

The first substrate is delimited downwardly by a first internal surface, and the second substrate is delimited upwardly by a second internal surface. The device further includes a first dielectric layer that extends on the first substrate, and a second dielectric layer that coats the cavity. The device further includes a first trench portion and a second trench portion, the first trench portion delimited laterally by a plurality of lateral walls. The first trench portion extends through the first substrate and delimits the suspended semiconductive region, with the second trench portion traverse to the first dielectric layer. The second trench portion extends through the first dielectric layer in direct communication with the first trench portion, the first and second trench portions together configured to form a single trench. The suspended structure includes a compensation region of the first internal surface that extends below the suspended semiconductive region.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A MEMS device, comprising:
a fixed body delimiting a cavity;
a suspended structure extending cantilevered from the fixed body, above the cavity, and comprising a suspended semiconductive region; and
a transducer above the suspended structure,
and wherein the suspended structure further comprises a compensation region of thermal oxide, which extends below the suspended semiconductive region.

2. The MEMS device according to claim 1, further comprising at least one compressive region above the suspended semiconductive region.

3. The MEMS device according to claim 2, wherein the compressive region comprises a front dielectric layer of thermal oxide, above the suspended semiconductive region.

4. The MEMS device according to claim 3, wherein the front dielectric layer contacts the suspended semiconductive region, and wherein the transducer is above the front dielectric layer.

5. The MEMS device according to claim 1, comprising an internal dielectric layer of thermal oxide, which coats the cavity and forms the compensation region.

6. A process for manufacturing a MEMS device, comprising:
forming a fixed body delimiting a cavity;
forming a suspended structure extending cantilevered from the fixed body, above the cavity, and comprising a suspended semiconductive region; and
forming a transducer above the suspended structure,
and wherein forming the suspended structure comprises forming a compensation region of thermal oxide, which extends below the suspended semiconductive region.

7. The manufacturing process according to claim 6, comprising forming at least one compressive region above the suspended semiconductive region.

8. The manufacturing process according to claim 7, wherein forming at least one compressive region comprises forming a front dielectric layer of thermal oxide, above the suspended semiconductive region.

9. The manufacturing process according to claim 6, wherein forming a fixed body comprises forming a semiconductor body delimited by a front surface and a bottom surface, the manufacturing process further comprising:
forming the cavity so that it is buried into the semiconductor body;
forming at least one opening which extends into the semiconductor body, between the cavity and one of the front surface and the bottom surface; and
performing a thermal oxidation process, so as to coat the cavity with an internal dielectric layer of thermal oxide, which forms the compensation region,
and wherein forming the suspended structure comprises releasing the suspended structure following the formation of the internal dielectric layer.

10. The manufacturing process according to claim 9, comprising forming the front dielectric layer by the thermal oxidation process.

11. The manufacturing process according to claim 9, comprising, by the thermal oxidation process:
increasing the thickness of the internal dielectric layer; and
causing the formation of a closing region of thermal oxide which closes the opening, sealing the cavity, so as to stop the increase in thickness of the internal dielectric layer before the end of the thermal oxidation process, in such a way that the thickness of the internal dielectric layer depends on the shape of the opening.

12. The manufacturing process according to claim 9, wherein forming at least one opening comprises forming, after forming the cavity and before performing the thermal oxidation process, a plurality of openings which extend between the cavity and the bottom surface, in such a way that the openings delimit a plurality of pillar semiconductive regions; and wherein the execution of the thermal oxidation process causes the formation, in each opening, of a corresponding closing region of thermal oxide, so as to seal the cavity; the manufacturing process further comprising:
selectively removing the closing regions; and
performing a thermal treatment so as to cause the formation, from the pillar semiconductive regions, of an additional cavity, which is of buried type and extends between the cavity and the bottom surface.

13. The manufacturing process according to claim 6, wherein forming a fixed body comprises forming a structure comprising an insulating layer and a top semiconductive substrate and a bottom semiconductive substrate, which are coupled by interposition of the insulating layer; the manufacturing process further comprising:
forming the cavity so that it is delimited upwardly by a part of the top semiconductive substrate and is delimited laterally by portions of the insulating layer and the bottom semiconductive substrate;
forming a trench which extends through the part of the top semiconductive substrate; and
performing a thermal oxidation process, so as to coat the cavity with an internal dielectric layer of thermal oxide, which forms the compensation region.

14. A device, comprising:
a structure having a first surface and a second surface opposite the first surface;
a first substrate on the first surface of the structure and a second substrate on the second surface of the structure;
an insulating layer between the first substrate and the second substrate, the insulating layer coupling the first and second substrate together;
a cavity in the structure delimited upwardly by a first portion of the first substrate;
a suspended structured extending cantilevered from the structure and comprising a suspended semiconductive region; and
a transducer on the suspended structure above the cavity.

15. The device of claim 14, wherein the first substrate is delimited downwardly by a first internal surface, and the second substrate is delimited upwardly by a second internal surface.

16. The device of claim 14, further comprising a first dielectric layer that extends on the first substrate, and a second dielectric layer that coats the cavity.

17. The device of claim 14, further comprising a first trench portion and a second trench portion, the first trench portion delimited laterally by a plurality of lateral walls.

18. The device of claim 17, wherein the first trench portion extends through the first substrate and delimits the suspended semiconductive region, with the second trench portion traverse to the first dielectric layer.

19. The device of claim 18, wherein the second trench portion extends through the first dielectric layer in direct communication with the first trench portion, the first and second trench portions together configured to form a single trench.

20. The device of claim 1, wherein the suspended structure comprises a compensation region of the first internal surface that extends below the suspended semiconductive region.
